(19) United States
(12) Patent Application Publication
(10) Pub. No.: US 2021/0006202 A1
(43) Pub. Date: Jan. 7, 2021

(54) Automatic Cleaning Vehicle for Photovoltaic Panels

(71) Applicant: Suraj Mohan, Chennai (IN)

(72) Inventor: Suraj Mohan, Chennai (IN)

(21) Appl. No.: 16/976,892

(22) PCT Filed: Feb. 28, 2019
(86) PCT No.: PCT/IN2019/050172

§ 371 Date: Aug. 31, 2020

(30) Foreign Application Priority Data
Mar. 1, 2018 (IN) 201841007832

(51) Int. Cl. H02S 40/10; B08B 1/00; B08B 1/04; B08B 13/00; B08B 3/08; B08B 5/02; B64C 39/02

(52) U.S. Cl. CPC H02S 40/10; B08B 1/002; B08B 1/04; B08B 13/00; B64C 2201/141; B08B 5/02; B64C 39/024; B64C 2201/12; B08B 3/08

(57) ABSTRACT

The invention discloses an automatic surface cleaning vehicle for photovoltaic (PV) panels (102) that is capable of moving on the surface of the said panel. The system comprises of a surface cleaning device (816) mounted on a retractable supporting frame which is collectively called as an Unmanned Autonomous Vehicle (UAV) (101). The invention provides for an automatic cleaning system that also collects data about the amount of dust accumulated on the surface of the photovoltaic panel (102) and details of any damage found on the surface. A motor driving circuit is further comprised in the unmanned, autonomous vehicle (101) to control direction and motion of the unmanned, autonomous vehicle (101).

### TECHNICAL FIELD

The field of invention relates to a system and method for cleaning solar panels. More specifically, the invention relates to an autonomous vehicle that travels on the surfaces of photovoltaic/solar panels and implements cleaning of the solar panels.

### BACKGROUND ART

Solar energy generation panels are installed at various residential and commercial places for various reasons including reducing costs in electricity, and generating and using clean energy.

One common factor seen in all solar panels used for different applications, is that all of them collect dust and debris over the course of time. The panels also tend to be affected by weather conditions, smog, bird droppings, etc. This layer of unwanted materials can prevent adequate sunlight from reaching the inside of the panel for efficient conversion into electricity.

It is found that the presence of this dust layer results in up-to 25% reduction in the generation of solar energy, and the efficiency loss of a completely uncleaned panel may even be as high as 30% which is inefficient and undesirable. Additionally, the cost of cleaning of each of these panels is also very high, since professional cleaners are required to clean the solar panels.

The existing systems disclose traditional methods of cleaning that use particular types of brushes and brush movement for the cleaning purposes. At times, the size and the movement of the cleaning brushes and the equipment may also result in the corners of the PV panels remaining unclean. Hence, these may not be very efficient in completely cleaning the surface.

Most of the times, these cleaning devices also require constant human intervention for various decision-making and inputs, and hence, are unable to function accurately without user input.

Thus, in the light of this discussion, there is a need for an automated solar panel cleaning device that requires minimal or no human intervention and which is efficient in the cleaning process.

Thus, in the light of this discussion, there is a need of an automated solar panel cleaning device that is easy to use and efficient in reducing power generation losses in the panels.

### OBJECT OF INVENTION

One object of the invention is to provide a device that cleans the surfaces of solar panels without any human intervention.

Another object of the invention is to provide a cleaning mechanism for solar panels that improves the efficiency and reduces the losses in power generation from a solar panel.

Another object of the invention is to provide a cleaning mechanism with a surveillance module to ensure better maintenance of the panels.

Another object of the invention is to provide an efficient cleaning device that employs different methods of dry and wet cleaning.

Another object of the invention is to provide an efficient cleaning device that uses magnets for achieving magnetic levitation over the solar panel during cleaning.

Another object of the invention is to provide an efficient cleaning device that uses suction cups for better grip on the solar panel during cleaning.

### SUMMARY OF INVENTION

The present invention provides a system and method for automatic cleaning of a photovoltaic panel. The system comprises a supporting frame that is mounted on the photovoltaic panel, and the supporting frame comprises of wheels that are capable of moving along the length of the photovoltaic panel on opposite sides of the photovoltaic panel. Further, the system in the invention also comprises an unmanned, autonomous vehicle in communication with a server, configured to move across the photovoltaic panel for cleaning purposes.

The unmanned, autonomous vehicle comprises a large frame mounted on the supporting frame, and also comprises a surface cleaning device that is configured to clean photovoltaic panel surfaces. The surface cleaning device is capable of moving vertically along a height of the large frame. The surface cleaning device further comprises cleaning components such as brushes, nozzles for spraying cleaning liquids, and blowing devices to blow off dust particles from surfaces of the photovoltaic panels. A motor driving circuit is further comprised in the unmanned, autonomous vehicle to control direction and motion of the unmanned, autonomous vehicle. The server comprised in the system comprises a data acquisition system that is configured to receive information from the unmanned, autonomous vehicle, and a triggering module to initiate cleaning processes in the surface cleaning device.

### BRIEF DESCRIPTION OF DRAWINGS

This invention is illustrated in the accompanying drawings, throughout which, like reference letters indicate corresponding parts in the various figures.

The embodiments herein will be better understood from the following description with reference to the drawings, in which:

FIG. 1 depicts/illustrates the environment in which the cleaning vehicle works, in accordance with the present invention.

FIG. 2 depicts/illustrates the components and the working of the cleaning vehicle, in accordance with the present invention.

FIG. 3 depicts/illustrates the mechanical components and the working of the server, in accordance with the present invention.

FIG. 4a depicts/illustrates a water nozzle present in the cleaning vehicle, in accordance with the present invention.

FIG. 4b depicts/illustrates brushes present in the cleaning vehicle, in accordance with the present invention.

FIG. 5a depicts/illustrates the retractable frame in a lateral position, in accordance with the present invention.

FIG. 5b depicts/illustrates the retractable frame in a vertical position, in accordance with the present invention.

FIG. 6 depicts/illustrates an exemplary embodiment showing a thermal imager installed on the cleaning vehicle, in accordance with the present invention.

FIG. 7 depicts/illustrates the flowchart of the working of the cleaning vehicle, in accordance with the present invention.

FIG. 8a depicts/illustrates an exemplary embodiment showing magnets installed on the cleaning vehicle for levitation, in accordance with the present invention.

FIG. 8b depicts/illustrates an exemplary embodiment showing magnets installed on the cleaning vehicle for levitation, in accordance with the present invention.

### DESCRIPTION OF EMBODIMENTS

The embodiments herein and the various features and advantageous details thereof are explained more fully with reference to the non-limiting embodiments that are illustrated in the accompanying drawings and/or detailed in the following description. Descriptions of well-known components and processing techniques are omitted so as to not unnecessarily obscure the embodiments herein. The examples used herein are intended merely to facilitate an understanding of ways in which the embodiments herein may be practice and to further enable those of skill in the art to practice the embodiments herein. Accordingly, the examples should not be construed as limiting the scope of the embodiments herein.

The embodiments herein below provide the details of an unmanned autonomous vehicle, further referred to as a UAV, which travels on the surfaces of photovoltaic panels, further referred to as PV panels, in order to clean them.

In the context of the present invention, a PV panel is a power system comprising solar panels that is capable of harnessing the solar energy readily available from the sun and converting it into electrical energy.

In the present disclosure, the server is a device capable of receiving and transmitting data, and triggering cleaning actions in the autonomous vehicle based on the acquired data.

To begin with, the invention discloses an autonomous surface-cleaning vehicle that does not require human intervention and is employed for cleaning photovoltaic (PV) panels that are installed on roof-tops or on ground level for electrical energy generation. The system, called a UAV as aforementioned, comprises of a moving device which is a surface-cleaning device mounted on a supporting frame. In a preferred embodiment, the supporting frame may be a retractable frame. The surface-cleaning device comprises various cleaning mechanisms like brushes and blowing devices to clean the dust or other dirt particles that settle on the PV panels. The UAV also comprises a surveillance module that monitors the levels of dust and/or damages on the PV panels and takes the required action accordingly. The system disclosed in the invention is also capable of utilizing the solar energy for powering up the batteries present intrinsically.

Referring now to the drawings, where similar reference characters denote corresponding features consistently throughout the figures, there are shown preferred embodiments.

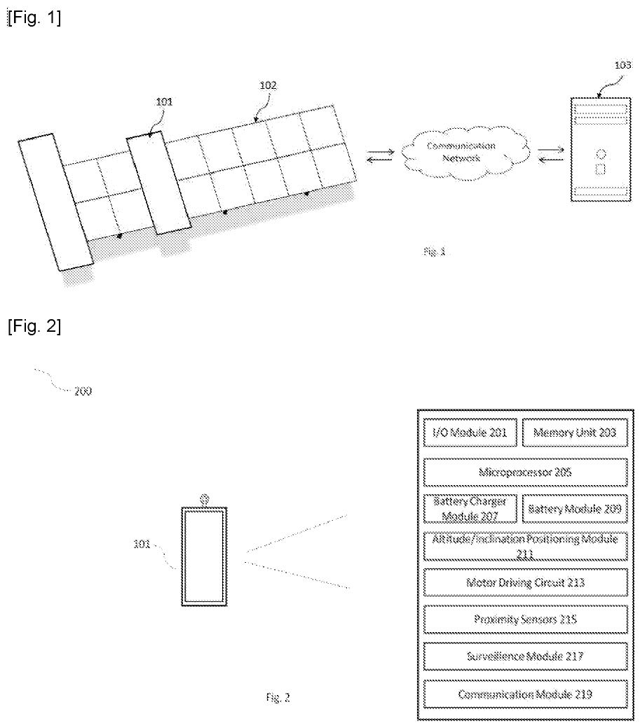

FIG. 1 illustrates the environment 100 in which the UAV works, with respect to one embodiment of the invention. The environment 100 depicts the UAV 101 installed on the PV panel 102. The UAV 101 is in communication with the server 103 via the communication network.

The said server 103 can be any device such as, but not limited to, a tablet, a mobile phone, a laptop, etc. that is disposed with a data acquisition system (not shown in the figure).

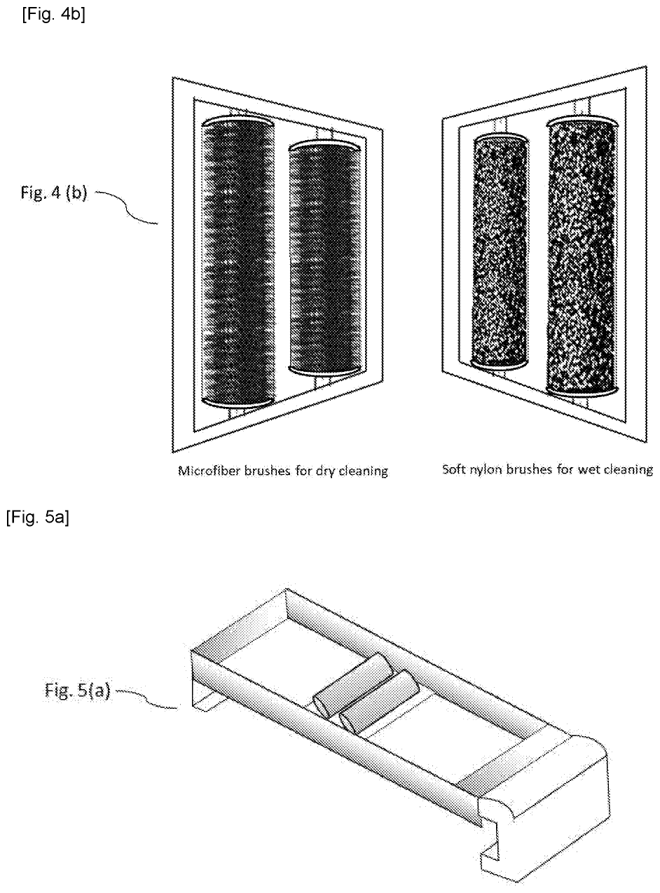

In one embodiment, the UAV 101 is a moving device that is capable of moving along the PV panel 102 in a vertical or a horizontal direction. It comprises of a large frame encompassing a smaller cleaning device that is embellished with several cleaning components such as cylindrical brushes (refer FIG. 4(b)) and nozzles for spraying water (refer FIG. 4(a)). The nozzles are mounted on a supporting frame that assists the lateral motion of the said system on the said panel.

In one embodiment, the supporting frame is equipped with flange wheels that traverse across the length of the PV panel 102 thus negating the need for external railings. The said wheels are positioned as hooks or clamps so as to handle various angles of mounting or inclination.

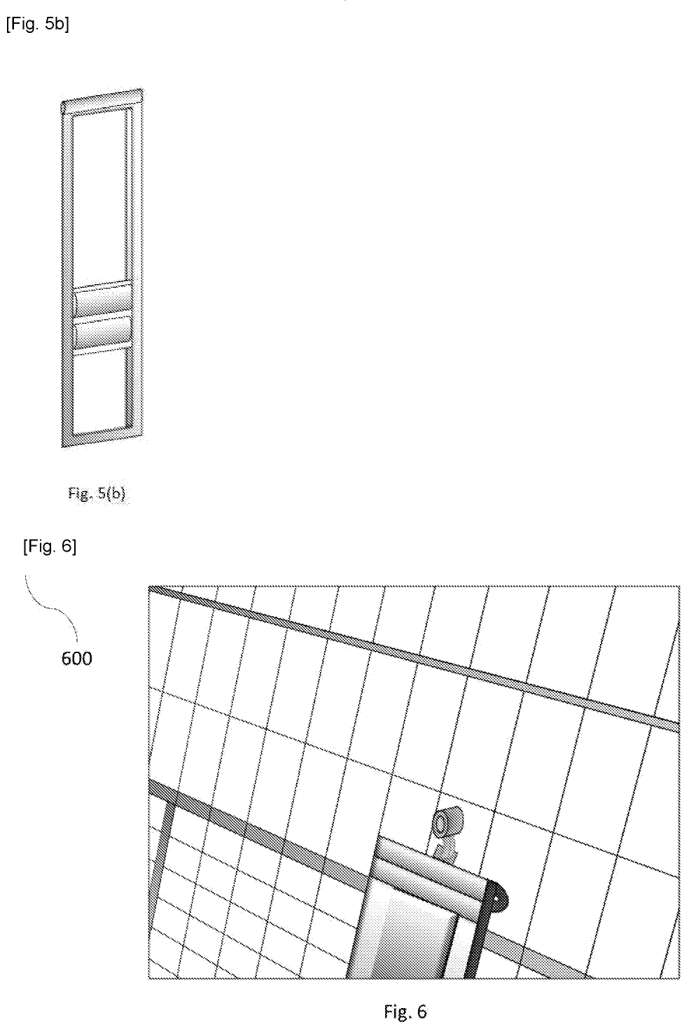

In one embodiment, the supporting frame is retractable in nature, i.e., it is capable of changing its length to span multiple PV panels in the vertical direction (refer FIG. 5(a) and FIG. 5(b)).

One embodiment of the UAV 101 makes use of magnetic levitation to allow the UAVs to hover over railings placed along the panels or the metal frame of the PV panel itself. This is achieved by using the current drawn from the solar panel and connecting them to the metal frame or railing creating a magnetic field. The polarity of the electromagnet is determined by the direction the current.

Further, magnets of opposite polarity are placed at specific positions below the UAV 101 to levitate it above the surface of the PV panel. Other magnets are placed along either side of the large frame (height-wise, on the y-axis) to allow the UAV to levitate across the series of PV panels.

Depending on the type of PV panels the UAV 101 is installed on, the frames in the UAV 101 are used. In one embodiment, if the UAV 101 is mounted on a ground installation of the PV panels, the larger frame (not shown in the figure) moves along the x-axis of the PV panels. The brushes (not shown in the figure) rotate around a fixed axis and the smaller unit (not shown in the figure) moves to and from across the surface of the panel. The said brushes can be easily attached and detached on a clip on-off design.

In one embodiment, in case the PV panels are installed on a roof-top, the smaller cleaning unit can be taken off from the larger frame to be used directly for cleaning the roof-tops. The said smaller unit can comprises suction cups (not shown in the figure) which work in a pre-defined systematic manner. The advantage of the suction cups attached to the smaller cleaning unit is to ensure that the smaller cleaning device is reliably secured to the PV panels, during a cleaning action or when the UAV 101 is in OFF or pause mode.

The UAV 101 also comprises of a surveillance module (not shown in the figure) that is capable of monitoring the levels of dust present on the PV panels and trigger the necessary cleaning action.

The UAV 101 is connected to the server 103 via a communication network. One skilled in the art may recognize that the network can be a wired or wireless communication network. The wired communication can be carried out by any one of the network configurations such as LAN, WAN, etc. and the wireless communication can be done through Mobile Service Provider (MSP) and Internet Service Provider (ISP) having internet connection provided by an ISP provider, 2G/3G/4G/5G internet connection provided by the mobile service provider. Such wired or wireless communication is not possible without the standard protocols as known in the art, where the standard protocols can be TCP/IP, HTTP, FTP, UDP, IPV4, IPV6 etc.

The server 103 comprises a data acquisition module (not shown in the figure) that stores the data recorded by the UAV 101 and evaluates the requirement for initiating the cleaning process automatically.

FIG. 2 illustrates the components disposed in the UAV 101, according to one embodiment of the present invention. The UAV 101 comprises of various components such as the I/O module 201 and the memory unit 203 that are used to receive and send inputs and outputs from and to other connected devices, and for storing data respectively. It also includes a microprocessor 205 that deals with the working of the system. The battery module 207 and the battery charger module 209 are essential to the working of the UAV 101 since they are the power source and the power generation device for the UAV 101.

The altitude/inclination positioning module 211 is disposed in the UAV 101 to measure the height at which the UAV 101 is mounted. The altitude/inclination positioning module 211 also measures the amount or angle of inclination that is required to position itself on the UAV 101 for cleaning purposes. The advantage is that the motor driving circuit 213 is used to control the motion and the direction of the UAV 101 on the said PV panels, while the proximity sensors 215 are employed to detect nearness of the UAV 101 to the extreme ends of the said PV panels in order to avoid damage by collision.

The UAV 101 can move along the said PV panels in a horizontal direction and a vertical direction. The motion is assisted by the motor driving circuit 213 and the proximity sensors 215 making sure that the UAV 101 does not skid or fall off during the cleaning process.

The surveillance module 217 is utilized to detect the level of dust or other undesirable particles on the surface of the said PV panels and the data from this module is sent to the server (not shown in the figure). The communication module 219 assists in this transfer of the recorded data.

The battery charger module 207 is enabled to harness the solar energy to generate power for the UAV 101. The said module utilizes the energy from the sun even when it is in an idle state and stores this converted electrical energy in the battery module 209 for further use.

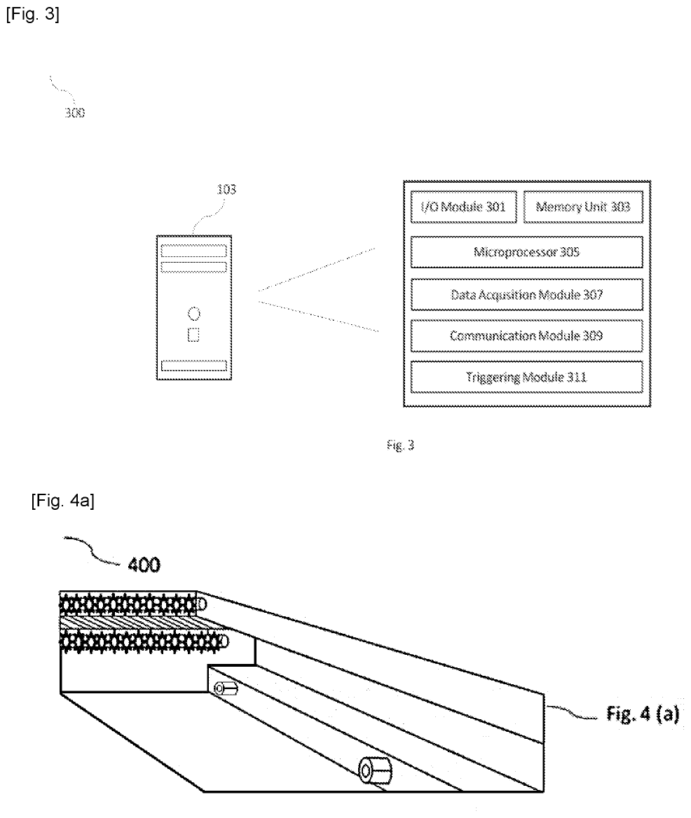

With respect to FIG. 3, the illustration pertains to the various components disposed in the server 103 and their working. The server 103 comprises of various components such as, but not limited to an I/O module 301, a memory unit 303, and a microprocessor 305.

The data acquisition module 307 disposed in the server 103 is responsible for acquiring, storing and assessing data that is received from the UAV 101 (not shown in the figure). It also sends a signal to the triggering module 311 to initiate the cleaning process in case the accumulation of dust on the said PV panels is found to be more than a pre-defined threshold value from the received data. The server 103 remains in communication with other connected devices via the communication module 309 disposed intrinsically.

FIG. 4(a) illustrates a water nozzle present intrinsically in the UAV 101 that is used to spray water on the panels during the wet cleaning process. A pre-defined amount of water is sprayed through these nozzles onto the panel to facilitate the cleaning process.

FIG. 4(b) illustrates the brushes that are present in the UAV 101 (not shown in the figure). In a preferred embodiment, the brushes in the UAV 101 may be made of microfiber materials that are utilized for dry cleaning of the PV panel 102 i.e. brushing off the dust on the panels, or the other type of cleaning brushes may be made up of soft nylon that are utilized for wet cleaning of the said panel. The lateral movement of the UAV 101 across the said PV panels 102 cleans the dust off the surfaces.

In one embodiment of the invention, the cleaning device may also have a vibrator present intrinsically to pre-dust the panels to reduce the formation of greasy textures after wet cleaning of the said panels.

FIG. 5(a) and FIG. 5(b) illustrate an exemplary embodiment of the supporting frame that is retractable in nature. The retractable property of the frame allows the UAV (not shown in the figure) to span multiple PV panels (not shown in the figure) and facilitate better cleaning of the said panels. FIG. 6 illustrates an exemplary embodiment of a thermal imager that is installed on the UAV 101 and acts as a surveillance module. The imager detects the temperature without contact based on the infrared energy emitted/transmitted/reflected by all materials and converts this factor of energy into a temperature reading.

FIG. 6 illustrates an exemplary embodiment of a thermal imager that is installed on the UAV 101 and acts as a surveillance module. The imager detects the temperature without contact based on the infrared energy emitted/transmitted/reflected by all materials and converts this factor of energy into a temperature reading.

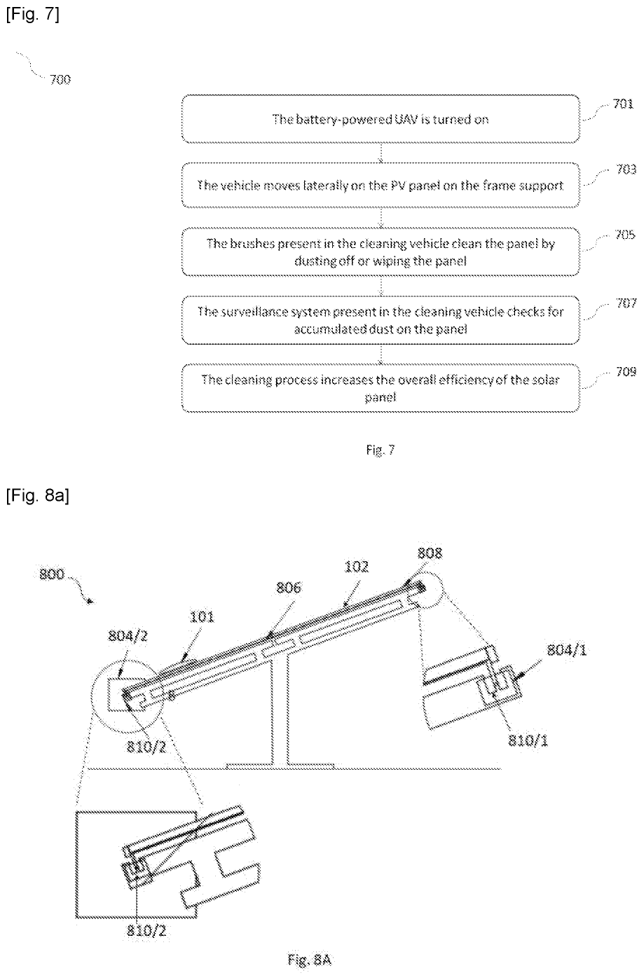

FIG. 7 illustrates the working of the said UAV according to one embodiment of the present invention. The battery-powered UAV is turned on, as depicted at step 701 when it begins moving laterally on the PV panel, as depicted at step 703. Subsequently, the UAV cleans the surface on which it is moving using the brushes present on the UAV body, as depicted at step 705. The surveillance system that is present in the UAV constantly checks for the amount of accumulated dust or damages on the surface of the PV panels, as depicted at step 707. The said cleaning process results in an increased efficiency of the whole system, as depicted at step 709.

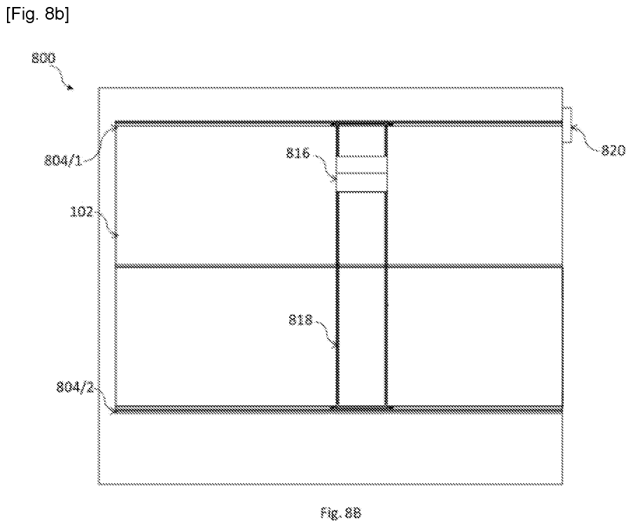

FIG. 8(a) depicts an exemplary embodiment 800 showing magnets installed on the cleaning vehicle for levitation, in accordance with the present invention. FIG. 8(a) depicts a side view of the PV panel 102 comprising the UAV 101. The supporting frame comprises magnets to enable the levitation of the UAV 101, according to one embodiment of the invention. The magnets comprised in the supporting frame may be in the form of magnetic strips 804/1 and 804/2 which are positioned along the upper and lower edge of the PV panel 102. The supporting frame along the edges of the PV panel 102 also comprises one or more sets of flange wheels 810/1 and 810/2 along the upper edge and the lower edge of the PV panel 102, respectively. In an embodiment, the magnetic strips 804/1 and 804/2 and the flange wheels 810/1 and 810/2 may be magnetic or electromagnetic in nature. The magnetic polarities of the flange wheels 810/1 and 810/2 are opposite to the polarities of the magnetic strips 804/1 and 804/2. Hence, the flange wheels 810/1 and 810/2 repel the magnetic strips 804/1 and 804/2 due to their opposite polarities, which causes the flange wheels 810/1 and 810/2 to levitate over the magnetic strips 804/1 and 804/2. Thus, as the UAV 101 is mounted on the flange wheels, the UAV 101 also levitates over the body of the PV panel 102. The advantage of the disclosed system and method is that the levitation of the UAV 101 allows it to achieve higher speed of movement with reduced friction. Subsequently, the system achieves lower energy consumption due to the efficient movement of the UAV 101.

FIG. 8(b) depicts an exemplary embodiment 800 showing magnets installed on the cleaning vehicle for levitation, in accordance with the present invention. FIG. 8(b) depicts a top view of the PV panel 102, comprising the UAV 101. The large frame 818 mounted on the supporting frame also comprises magnets to enable the levitation of the cleaning device 816 over the large frame 818. Additionally, the supporting frame comprises a magnet 820 at one corner of the PV panel 102 to enable the sideways movement of the UAV device 101, namely, a longitudinal movement of the large frame 818 over the supporting frame.

In an embodiment, one or more motors may be used to enable the movement of the UAV device 101. When the UAV device 101 is being levitated over the PV panel 102, fewer motors may be required to enable the movement of the UAV device 101.

The magnets may be arranged in a Hallbach array to augment the magnetic field for the levitation of the UAV 101, according to one embodiment of the invention. In another embodiment, superconductors may be used to achieve diamagnetic levitation of the UAV 101. Alternatively, pyrolytic graphite may be levitated by placing thin squares of pyrolytic graphite above four magnets, where the north poles of the four magnets form a diagonal and the south poles of the magnet form another diagonal.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the scope of the embodiments as described herein.

1. An automatic cleaning system for cleaning a photovoltaic panel (102), the automatic cleaning system comprising:
at least one supporting frame mounted on the photovoltaic panel (102), said supporting frame further comprising:
one or more sets of wheels capable of moving on the at least one supporting frame along a length of the photovoltaic panel (102);
at least one unmanned, autonomous vehicle (101) configured to move on said photovoltaic panel (102) using the one or more sets of wheels, the unmanned, autonomous vehicle (101) further comprising:
at least one large frame mounted on said supporting frame;
at least one surface cleaning device mounted on said large frame, the surface cleaning device further comprising:
at least one set of cleaning components configured to clean said photovoltaic panel (102);
at least one motor driving circuit (213) configured to control motion and direction of the unmanned, autonomous vehicle (101); and
at least one server (103) configured to communicate with the unmanned, autonomous vehicle (101), the server (103) further comprising:
one or more data acquisition modules (307) configured to receive data from the unmanned, autonomous vehicle (101); and
one or more triggering modules (311) configured to trigger one or more cleaning actions of the unmanned, autonomous vehicle (101)

2. The system as claimed in claim 1, wherein the supporting frame comprises:
magnetic strips (804/1, 804/2) positioned along one or more of an upper edge and lower edge of the PV panel 102);
one or more sets of flange wheels (810/1, 810/2) positioned along the upper edge and the lower edge of the PV panel (102) respectively, wherein the magnetic strips (804/1, 804/2) and the flange wheels (810/1, 810/2) are magnetic or electromagnetic, wherein the magnetic polarities of the flange wheels (810/1, 810/2) are reversed with respect to the magnetic polarities of the magnetic strips (804/1, 804/2) to levitate the flange wheels (810/1, 810/2) over the magnetic strips (804/1, 804/2).

3. The system as claimed in claim 1, wherein the surface cleaning device is configured to move vertically along the length of the large frame by using the at least one motor driving circuit (213), wherein the surface cleaning device comprises suction cups to enable attachment of the surface cleaning device to the photovoltaic panel (102), and wherein the said set of cleaning components comprise one or more of cleaning brushes, blowing devices configured to blow off dust particles from surface of the photovoltaic panel (102), and nozzles for spraying cleaning liquid on to the surface of the photovoltaic panel (102).

4. The system as claimed in claim 1, wherein the unmanned, autonomous vehicle (101) further comprises at least one proximity sensor configured to detect a proximity of the unmanned, autonomous vehicle (101) to extreme ends of the photovoltaic panel (102), and wherein the unmanned, autonomous vehicle (101) further comprises at least one altitude/inclination positioning module (211) configured to detect a measure of inclination required by the surface cleaning device for cleaning purposes and for measuring the height at which the unmanned, autonomous vehicle (101) is mounted.

5. The system as claimed in claim 1, wherein the surface cleaning device further comprises at least one surveillance module (217) configured to detect a level of dust particles on the surface of the photovoltaic module (102), and wherein the data acquisition module (307) comprised in the server (103) is configured to receive data from the surveillance module (217) over a communication network, and is further configured to trigger a cleaning action in the surface cleaning device via the triggering module (311).

6. A method for cleaning a photovoltaic panel (102) using an unmanned, autonomous vehicle (101), the method comprising:
mounting a supporting frame over a photovoltaic panel (102);
mounting the unmanned, autonomous vehicle (101) over the supporting frame;
moving a surface cleaning device comprised in the unmanned, autonomous vehicle (101) vertically and horizontally across the length of the photovoltaic panel (102);
acquiring data about levels of dust on surface of the photovoltaic panel (102) through a surveillance module (217);
sending acquired data to a server (103) via a communication module;
receiving a trigger to initiate cleaning process from the server (103) via a triggering module (311) comprised in the server (103).

7. The method as claimed in claim 6, wherein the surface cleaning device is configured to move vertically along the length of the large frame by using the at least one motor driving circuit (213), wherein the surface cleaning device comprises suction cups to enable attachment of the surface cleaning device to the photovoltaic panel (102), and wherein the said set of cleaning components comprise one or more of cleaning brushes, blowing devices configured to blow off dust particles from surface of the photovoltaic panel (102), and nozzles for spraying cleaning liquid on to the surface of the photovoltaic panel (102).

8. The method as claimed in claim 6, wherein the unmanned, autonomous vehicle (101) further comprises at least one proximity sensor configured to detect a proximity of the unmanned, autonomous vehicle (101) to extreme ends of the photovoltaic panel (102), and wherein the unmanned, autonomous vehicle (101) further comprises at least one altitude/inclination positioning module (211) configured to detect a measure of inclination required by the surface cleaning device for cleaning purposes and for measuring the height at which the unmanned, autonomous vehicle (101) is mounted.

9. The method as claimed in claim 6, wherein the surface cleaning device further comprises at least one surveillance module (217) configured to detect a level of dust particles on the surface of the photovoltaic module (102), and wherein the data acquisition module (307) comprised in the server (103) is configured to receive data from the surveillance module (217) over a communication network, and is further configured to trigger a cleaning action in the surface cleaning device via the triggering module (311).

10. The method as claimed in claim 6, wherein the method comprises:
positioning magnetic strips (804/1, 804/2) along the upper and lower edge of the PV panel 102);
positioning one or more sets of flange wheels (810/1, 810/2) along the upper edge and the lower edge of the PV panel (102) respectively, wherein the magnetic strips (804/1, 804/2) and the flange wheels (810/1, 810/2) are magnetic or electromagnetic;
reversing the magnetic polarities of the flange wheels (810/1, 810/2) with respect to the magnetic polarities of the magnetic strips (804/1, 804/2); and
levitating the flange wheels (810/1, 810/2) over the magnetic strips (804/1, 804/2).
